(19) United States
(12) Patent Application Publication
(10) Pub. No.: US 2025/0167049 A1
(43) Pub. Date: May 22, 2025

(54) WAFER PROCESSING METHOD

(71) Applicant: DISCO CORPORATION, Tokyo (JP)

(72) Inventor: Masaru NAKAMURA, Tokyo (JP)

(21) Appl. No.: 18/926,822

(22) Filed: Oct. 25, 2024

(30) Foreign Application Priority Data
Nov. 21, 2023 (JP) 2023-197439

(51) Int. Cl. H01L 21/78; H01L 21/02

(52) U.S. Cl. CPC H01L 21/78; H01L 21/02076

(57) ABSTRACT

A wafer processing method includes a division initiating point forming step of forming division initiating points in projected dicing lines, a sheet disposing step of disposing, on a wafer, a sheet having elasticity, before or after the division initiating point forming step, and a splitting-up step of splitting the wafer into individual device chips by expanding the sheet and applying external force to the wafer. The splitting-up step includes an adhesive liquid coating step of coating an exposed surface of the wafer with adhesive liquid having fluidity before or after the sheet is expanded and causing the adhesive liquid to enter dividing grooves formed by the splitting-up of the wafer.

### BACKGROUND OF THE INVENTION

### Field of the Invention

The present invention relates to a wafer processing method of dividing, into individual device chips, a wafer which has a face side on which a plurality of devices are formed by being partitioned by a plurality of projected dicing lines.

### Description of the Related Art

Wafers which each have a face side on which a plurality of devices exemplified by integrated circuits (ICs) and large scale integration (LSI) circuits are formed by being partitioned by a plurality of intersecting projected dicing lines are ground on a reverse side thereof and formed into a predetermined thickness. Thereafter, the wafers are divided into individual device chips by a dicing apparatus or a laser processing apparatus, and the divided device chips are then used for electronic appliances including mobile phones and personal computers.

There has also been proposed a technology that applies, to a wafer, a laser beam having a wavelength transmittable through the wafer by positioning a focused spot of the laser beam at an inner portion of the wafer corresponding to the relevant projected dicing line, forms a modified layer that serves as a division initiating point, and thereafter applies external force to the wafer to divide the wafer into individual device chips (see, for example, Japanese Patent No. 3408805).

Further, the present applicant has proposed a technology that applies, to a wafer, a laser beam having a wavelength transmittable through the wafer by positioning a focused spot of the laser beam at an inner portion of the wafer corresponding to the relevant projected dicing line, forms a modified layer that serves as a division initiating point, and thereafter grounds a reverse side of the wafer to finish the wafer into a desired thickness and divide the wafer into individual device chips (see, for example, Japanese Patent Laid-open No. 2014-78569).

### SUMMARY OF THE INVENTION

However, dividing, into individual device chips, the wafer in which a modified layer is formed at an inner portion corresponding to the respective projected dicing line by applying external force to the wafer allows dust to scatter by breaking of the modified layer and adhere to face sides of the device chips, causing the problem of reduced quality of device chips.

Moreover, residues of the broken modified layer adhere to side surfaces of the device chips. These residues of the modified layer may fall off and scatter from the side surfaces of the device chips and hinder bonding in the subsequent steps including a pick-up step, a wire bonding step, a die bonding step, and a device chip laminating step. Further, these residues may adhere to the face sides of the device chips and cause the problem of reduced quality of the laminated device chips.

Further, grinding swarf that is generated upon grinding may intrude into dividing grooves formed in the projected dicing lines and adhere to the side surfaces of the device chips, causing the problem of reduced quality of the device chips in the subsequent steps as described above.

Such a problem may also occur in a technology called dicing before grinding in which projected dicing lines are formed with grooves each having a depth corresponding to a finishing thickness of the device chips, as division initiating points, the reverse side of the wafer is ground until the finishing thickness of the device chips is reached, and the wafer is divided into individual device chips (see, for example, Japanese Patent Laid-open No. Hei 11-40520).

It is accordingly an object of the present invention to provide a wafer processing method that is capable of solving the problem caused by processing swarf adhered to the side surfaces and the face sides of the device chips.

In accordance with an aspect of the present invention, there is provided a wafer processing method that divides a wafer which has a face side on which a plurality of device chips are formed by being partitioned by a plurality of projected dicing lines into individual device chips, the method including a division initiating point forming step of forming division initiating points in the projected dicing lines, a sheet disposing step of disposing, on the wafer, a sheet having elasticity before or after the division initiating point forming step, an adhesive liquid coating step of coating an exposed surface of the wafer with adhesive liquid having fluidity, a splitting-up step of splitting up the wafer into individual device chips by expanding the sheet and applying external force to the wafer, a solidified film forming step of forming a solidified film by solidifying the adhesive liquid in a state in which the sheet is expanded, after the splitting-up step, and a processing swarf removal step of removing processing swarf adhered to side surfaces of the device chips by peeling off the solidified film. In the splitting-up step, the adhesive liquid that has coated the exposed surface of the wafer in the adhesive liquid coating step is caused to enter dividing grooves formed by the splitting-up of the wafer.

In accordance with another aspect of the present invention, there is provided a wafer processing method that divides a wafer which has a face side on which a plurality of devices are formed by being partitioned by a plurality of projected dicing lines into individual device chips, the method including a division initiating point forming step of forming division initiating points in the projected dicing lines, a protective member disposing step of disposing a protective member that protects the face side of the wafer, before or after the division initiating point forming step, a reverse side grinding step of finishing the wafer to a desired thickness by holding the protective member side on a chuck table and grinding a reverse side of the wafer after the division initiating point forming step, while dividing the wafer into individual device chips by forming dividing grooves in the projected dicing lines, a sheet disposing step of disposing a sheet having elasticity on the reverse side of the wafer and removing the protective member from the face side of the wafer, an adhesive liquid coating step of coating an exposed surface of the wafer with adhesive liquid having fluidity, an expanding step of expanding the sheet to expand a spacing between the individual device chips, a solidified film forming step of forming a solidified film by solidifying the adhesive liquid in a state in which the sheet is expanded, after the expanding step, and a processing swarf removal step of removing processing swarf adhered to side surfaces of the device chips by peeling off the solidified film. In the expanding step, the adhesive liquid that has coated the wafer in the adhesive liquid coating step is caused to enter the dividing grooves.

Preferably, in the division initiating point forming step, modified layers that serve as the division initiating points are formed by application of a laser beam having a wavelength transmittable through the wafer to the wafer with a focused spot of the laser beam being positioned inside the wafer corresponding to the projected dicing lines.

Preferably, the wafer processing method further includes a cleaning step of cleaning the wafer after the processing swarf removal step.

Preferably, the adhesive liquid is water-soluble resin including any of polyvinyl alcohol, polyethylene oxide, polyacrylamide, carboxymethylcellulose, resol-type phenolic resin, methylol urea resin, methylol melamine resin, vinyl acetate resin emulsion adhesive agent, and (polyvinyl alcohol (PVA)+borax) or silicon-based adhesive resin.

According to the wafer processing method of the present invention, the adhesive liquid having fluidity captures the processing swarf that has adhered to the side surfaces of the device chips. Hence, peeling off the solidified film obtained by the adhesive liquid being solidified makes it possible to remove the processing swarf from the side surfaces of the device chips. As a result, the processing swarf would not fall off or scatter from the side surfaces of the device chips in the subsequent steps including wire bonding, die bonding, lamination of device chips, and the like. Moreover, even if processing swarf is adhered to the face sides of the device chips, peeling off the solidified film also allows the processing swarf to be removed from the face sides of the device chips. Therefore, the present invention is capable of solving the problem caused by the processing swarf adhered to the side surfaces and the face sides of the device chips.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view illustrating a sheet disposing step according to a first embodiment of the present invention;

FIG. 1B is a perspective view of a frame unit including a wafer in which a sheet is disposed;

FIG. 2A is a perspective view at a time when a laser beam is applied from a face side of the wafer and a modified layer is formed in a division initiating point forming step;

FIG. 2B is a perspective view at a time when a laser beam is applied from a reverse side of the wafer and a modified layer is formed in the division initiating point forming step;

FIG. 3A is a perspective view of the frame unit including the wafer in which modified layers are formed along projected dicing lines;

FIG. 3B is a cross sectional view of the wafer in which modified layers are formed along projected dicing lines;

FIG. 4 is a perspective view illustrating an expanding apparatus and an adhesive liquid coating apparatus;

FIG. 5 is a cross sectional view illustrating an adhesive liquid coating step;

FIG. 6 is a cross sectional view illustrating a splitting-up step;

FIG. 7 is a cross sectional view illustrating a state in which a frame support section is brought back to its original position;

FIG. 8 is a cross sectional view illustrating a state in which a slack sheet between the wafer and an annular frame is heated and shrunk;

FIG. 9A is a perspective view of the wafer in which a solidified film is formed on the face side;

FIG. 9B is a cross sectional view of the wafer in which the solidified film is formed on the face side;

FIG. 10A is a perspective view of a frame unit including a wafer from which processing swarf has been removed;

FIG. 10B is a cross sectional view of the wafer from which processing swarf has been removed;

FIG. 11 is a perspective view illustrating a protective member disposing step in a second embodiment of the present invention;

FIG. 12A is a perspective view at a time when modified layers are formed in the division initiating point forming step;

FIG. 12B is a cross sectional view of the wafer in which modified layers are formed along the projected dicing lines;

FIG. 12C is a perspective view of the wafer in which the modified layers are formed along the projected dicing lines;

FIG. 13 is a perspective view at a time when grooves each having a depth corresponding to a finishing thickness of device chips are formed by ablation processing in the division initiating point forming step;

FIG. 14 is a perspective view in a case where grooves each having a depth corresponding to the finishing thickness of the device chips are formed by cutting processing in the division initiating point forming step;

FIG. 15A is a perspective view illustrating a state in which a protective member is disposed on the face side of the wafer in which grooves each having a depth corresponding to the finishing thickness of the device chips are formed along the projected dicing lines;

FIG. 15B is a cross sectional view illustrating the state in which the protective member is disposed on the face side of the wafer illustrated in FIG. 15A;

FIG. 16A is a perspective view illustrating a reverse side grinding step;

FIG. 16B is a perspective view of the wafer in which dividing grooves are formed;

FIG. 17A is a perspective view illustrating a state in which an elastic sheet is disposed on the reverse side of the wafer in a sheet disposing step; and

FIG. 17B is a perspective view illustrating a state in which the protective member is removed from the face side of the wafer in the sheet disposing step.

### DETAILED DESCRIPTION OF THE PREFERRED EMBODIMENTS

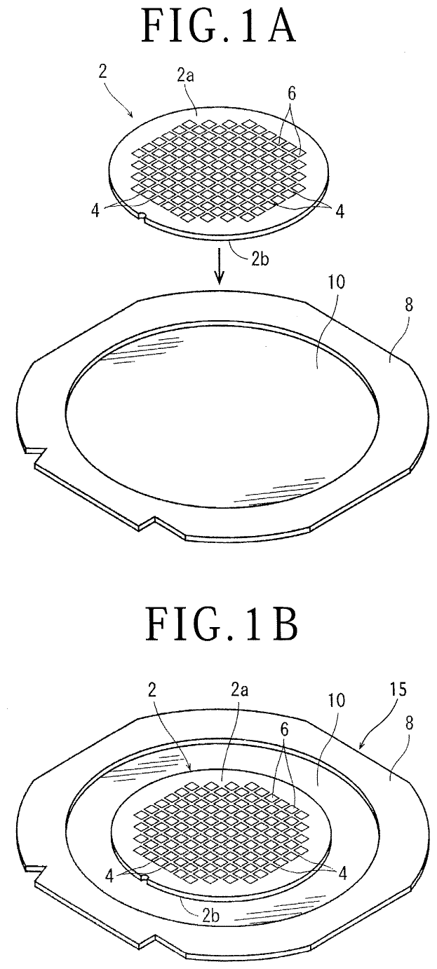

First, a wafer processing method according to a first embodiment of the present invention will be explained with reference to FIGS. 1A through 10B.

FIG. 1A illustrates a circular plate-shaped wafer 2 to which processing according to the wafer processing method of the present invention is to be applied. The wafer 2 may, for example, be formed of an appropriate semiconductor material such as silicon. A face side 2a of the wafer 2 is partitioned into a plurality of rectangular regions by a plurality of projected dicing lines 4 set in a grid pattern. In each of the plurality of rectangular regions, a device 6 such as an IC or an LSI circuit is formed.

In the present embodiment, first, a sheet disposing step of disposing the wafer 2 on an elastic sheet is performed. Yet, the sheet disposing step may be performed after a division initiating point forming step to be described later. In the sheet disposing step, as illustrated in FIG. 1A, the wafer 2 is disposed on a circular sheet 10 whose peripheral edge is fixed to an annular frame 8, and then the wafer 2 and the sheet 10 are integrated to form a frame unit 15. The sheet 10 may be an adhesive tape having an adhesive layer on one side (for example, an adhesive tape made of vinyl chloride). In this case, a reverse side 2b of the wafer 2 is affixed to the adhesive surface of the sheet 10 (see FIG. 1B). Further, the sheet 10 to be used in the sheet disposing step may be a thermocompression sheet including no adhesive layer. A thermocompression sheet is a sheet that is made of thermo-reversible synthetic resin (for example, polyolefin resin) and that exerts adhesive force when it softens or melts by being heated to a temperature near the melting point.

In the present embodiment, after the sheet disposing step is carried out, the division initiating point forming step of forming division initiating points in the projected dicing lines 4 is performed.

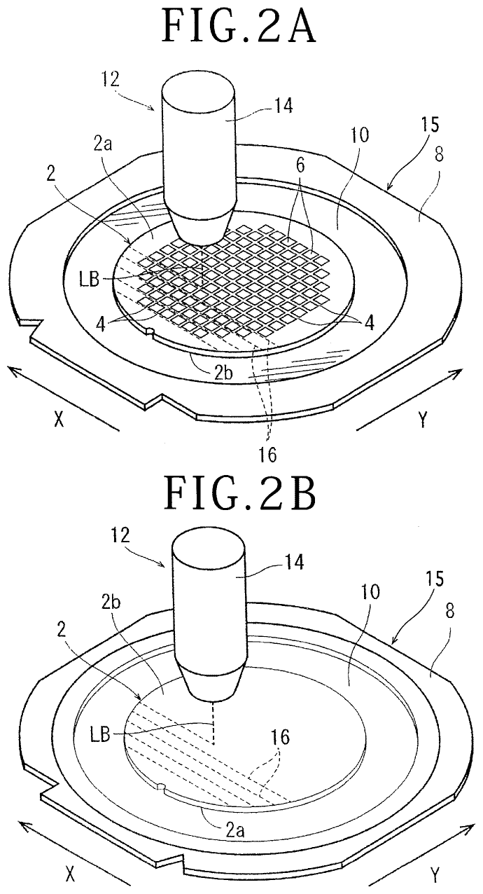

The division initiating point forming step can, for example, be performed by a laser processing apparatus 12 illustrated in FIG. 2A. The laser processing apparatus 12 includes a chuck table (not illustrated) that holds under suction the wafer 2, a laser oscillator (not illustrated) that emits a pulsed laser beam LB having a wavelength transmittable through the wafer 2, a light condenser 14 that converges the pulsed laser beam LB emitted from the laser oscillator and applies the laser beam LB to the wafer 2 held under suction on the chuck table, and an imaging unit (not illustrated) that images the wafer 2 held under suction on the chuck table.

The chuck table is rotatable about a vertical direction as an axis and is movable in an X-axis direction indicated by an arrow X illustrated in FIG. 2A and a Y-axis direction (a direction illustrated by an arrow Y in FIG. 2A) perpendicular to the X-axis direction. Note that an X-Y plane defined by the X-axis direction and the Y-axis direction is substantially horizontal.

In the division initiating point forming step, first, the face side 2a of the wafer 2 is faced upward, and the wafer 2 is held under suction on an upper surface of the chuck table. Next, the wafer 2 is imaged from an upper side by the imaging unit, and the projected dicing lines 4 in a first direction are aligned in the X-axis direction in reference to the image of the wafer 2 captured by the imaging unit. Further, the laser beam LB is focused on the projected dicing line 4 aligned in the X-axis direction, and a focused spot of the laser beam LB is positioned inside the projected dicing line 4.

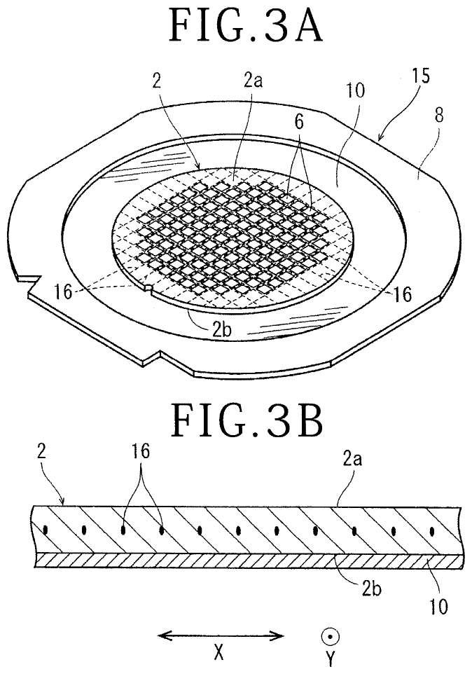

Subsequently, while the chuck table is being processing fed in the X-axis direction, the laser beam LB having a wavelength transmittable through the wafer 2 is applied to the wafer 2 from the light condenser 14. As a result, a modified layer 16 that serves as a division initiating point is formed inside the wafer 2 along the projected dicing line 4 (see FIG. 3B). Then, the chuck table is indexing fed in the Y-axis direction relative to the light condenser 14 by a spacing between adjacent projected dicing lines 4 in the Y-axis direction. Further, by application of the laser beam LB and the indexing feed of the chuck table alternately being repeated, the modified layers 16 are formed inside the wafer 2 along all of the projected dicing lines 4 in the first direction that have been aligned in the X-axis direction.

Next, after the chuck table is rotated by 90 degrees, application of the laser beam LB and indexing feed of the chuck table are alternately repeated. As a result, modified layers 16 are formed inside the wafer 2 along all of the projected dicing lines 4 in a second direction that are perpendicular to the projected dicing lines 4 in the first direction in which the modified layers 16 have already been formed. Performing the division initiating point forming step in this manner forms the modified layers 16 in a grid pattern in the wafer 2 along the projected dicing lines 4 formed in a grid pattern, as illustrated in FIG. 3A.

The division initiating point forming step as described above can be performed, for example, under the following processing conditions.
Wavelength of pulsed laser beam: 1,342 nm
Average output: 1.0 W
Repetition frequency: 90 kHz
Feeding speed: 700 mm/s

Here, an example in which the modified layers 16 are formed by application of the laser beam LB from the face side 2a of the wafer 2 has been explained. Yet, in the division initiating point forming step, as illustrated in FIG. 2B, the modified layers 16 may be formed by application of the laser beam LB from the reverse side 2b of the wafer 2. In this case, since the face side 2a of the wafer 2 comes into contact with a holding surface of the chuck table, a protective member is preferably disposed on the face side 2a of the wafer 2.

Further, in a case where the laser beam LB is to be applied from the reverse side 2b of the wafer 2, the imaging unit of the laser processing apparatus 12 would have a configuration including an ordinary image capturing element (for example, a charge coupled device (CCD)) that images the wafer 2 via the sheet 10 by a visible beam, infrared ray application means that applies infrared rays that transmit through the wafer 2, an optical system that captures the infrared rays applied from the infrared ray application means, and an image capturing element (infrared CCD) that outputs electric signals corresponding to the infrared rays captured by the optical system. Further, after the wafer 2 is held under suction on the upper surface of the chuck table with the reverse side 2b of the wafer 2 facing upward, infrared rays are applied from the imaging unit, and the face side 2a of the wafer 2 is imaged by the infrared rays that have been transmitted through the reverse side 2b of the wafer 2. As a result, the projected dicing lines 4 in the first direction can be aligned in the X-axis direction in reference to the image of the wafer 2 captured by the imaging unit. Thereafter, applying the laser beam LB to the wafer 2 in the manner described above forms the modified layers 16 in a grid pattern in the wafer 2 along the projected dicing lines 4 in the grid pattern.

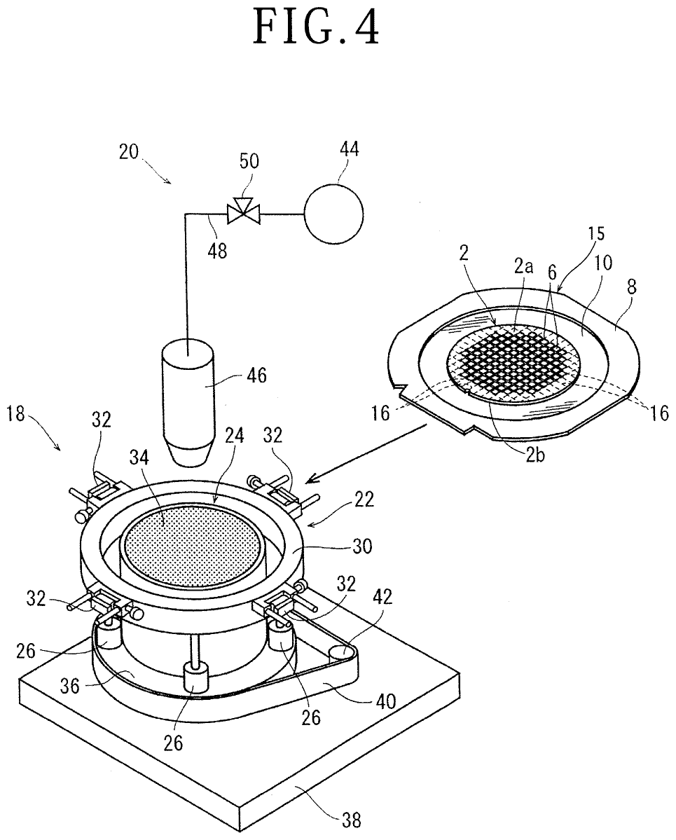

After the division initiating point forming step is carried out, a splitting-up step of splitting up the wafer 2 into individual device chips 6 by expanding the sheet 10 and applying external force to the wafer 2 is performed. The splitting-up step includes an adhesive liquid coating step of coating an exposed surface (face side 2a) of the wafer 2 with adhesive liquid having fluidity before or after the sheet 10 is expanded and causing the adhesive liquid to enter splitting-up grooves formed by the splitting-up. The splitting-up step and the adhesive liquid coating step may be performed, for example, by an expanding apparatus 18 and an adhesive liquid coating apparatus 20 that are illustrated in FIG. 4.

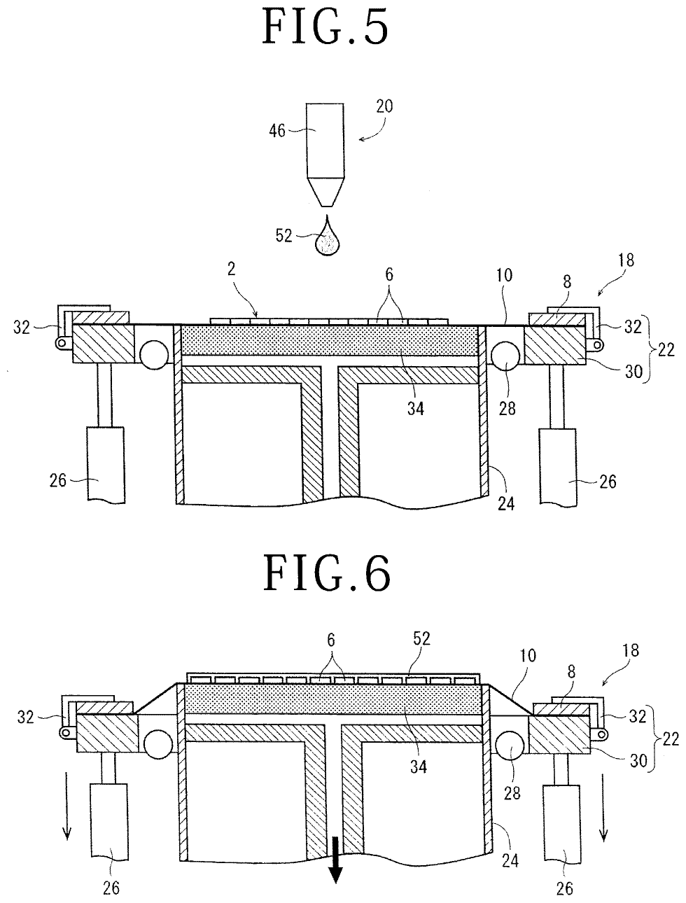

Described with reference to FIG. 4 together with FIG. 5, the expanding apparatus 18 includes a frame support section 22 that supports the annular frame 8, a wafer support section 24 that supports the wafer 2 via the sheet 10, an expanding mechanism 26 that expands the sheet 10 by separating the frame support section 22 and the wafer support section 24 relative from each other, and a shrink unit 28 (see FIG. 5) that heats and shrinks the slack sheet 10.

The frame support section 22 includes an annular member 30 and a plurality of clamps 32 that are established on an outer periphery of the annular member 30 at intervals in a circumferential direction. An outer diameter and an inner diameter of the annular member 30 correspond to an outer diameter and an inner diameter of the annular frame 8, so that the annular frame 8 can be placed on an upper surface of the annular member 30. The frame support section 22 fixes and supports the annular frame 8 placed on the annular member 30, by the clamps 32.

On an upper end portion of the wafer support section 24, a circular suction chuck 34 is disposed. The suction chuck 34 is formed of a porous member such as porous ceramic. Further, the suction chuck 34 is connected to suction means (not illustrated). In the wafer support section 24, suction force is generated on an upper surface of the suction chuck 34 by suction means, and the wafer 2 placed on the upper surface of the suction chuck 34 is held under suction.

The wafer support section 24 has a cylindrical shape and is disposed on an inner side in a radial direction of the frame support section 22. A gap is formed between an outer periphery of the wafer support section 24 and an inner periphery of the annular member 30 of the frame support section 22. Further, as illustrated in FIG. 4, the wafer support section 24 according to the present embodiment is fixed to an upper surface of a rotation plate 36. The rotation plate 36 is mounted in a rotatable manner on a board 38 of the expanding apparatus 18. The board 38 has a motor 42 that is established thereon and that rotates the rotation plate 36 via a belt 40.

The expanding mechanism 26 includes a plurality of air cylinders that lift and lower the frame support section 22. Upper ends of pistons of the plurality of air cylinders are coupled to the annular member 30 of the frame support section 22. Further, lower ends of the plurality of air cylinders are fixed to an upper surface of the circular rotation plate 36. Further, by the annular member 30 of the frame support section 22 being lowered with the pistons of the plurality of air cylinders in the expanding mechanism 26, the frame support section 22 and the wafer support section 24 are separated relatively from each other. This causes tension to be applied to the sheet 10 fixed to the annular frame 8 supported by the frame support section 22, and the wafer 2 formed with the division initiating points is split into individual device chips 6. Note that the expanding mechanism 26 may be one that lifts and lowers the wafer support section 24 relative to the frame support section 22.

As illustrated in FIG. 5, the shrink unit 28 has an annular shape and is disposed between the frame support section 22 and the wafer support section 24. Further, by sending hot air or applying infrared rays toward the upper side, the shrink unit 28 heats and shrinks the slack sheet 10 between the wafer 2 and the annular frame 8. Note that the shrink unit 28 is coupled to the frame support section 22 via an appropriate bracket (not illustrated) and is lifted and lowered together with the frame support section 22.

With reference to FIG. 4, the adhesive liquid coating apparatus 20 will be described. The adhesive liquid coating apparatus 20 includes an adhesive liquid supply source 44, a nozzle 46 that drops the adhesive liquid supplied from the adhesive liquid supply source 44 on the exposed surface of the wafer 2 supported by the wafer support section 24 of the expanding apparatus 18, a pipe conduit 48 that connects the adhesive liquid supply source 44 and the nozzle 46, and an on/off valve 50 that is installed in the pipe conduit 48.

In the splitting-up step, first, the annular frame 8 is supported by the frame support section 22, and the wafer 2 is supported by the wafer support section 24. Specifically, as illustrated in FIG. 5, the annular frame 8 is placed on the annular member 30 of the frame support section 22, and is then fixed to the annular member 30 by the clamps 32. The wafer 2 is placed on the suction chuck 34 of the wafer support section 24 via the sheet 10, with the face side 2a facing upward. At this time, the height of the upper surface of the frame support section 22 and the height of the upper surface of the wafer support section 24 are made substantially the same. Further, at this point in time, suction means of the wafer support section 24 is not actuated, and the wafer 2 is not held under suction by the suction chuck 34.

After the annular frame 8 is supported by the frame support section 22 and the wafer 2 is supported by the wafer support section 24 in the splitting-up step, the adhesive liquid coating step of coating the exposed surface (face side 2a) of the wafer 2 with the adhesive liquid having fluidity and causing the adhesive liquid to enter the splitting-up grooves formed by the splitting-up is performed. The face side 2a of the wafer 2 may be coated with the adhesive liquid before or after the sheet 10 is expanded. Yet, in the present embodiment, an example in which the face side 2a of the wafer 2 is coated with the adhesive liquid before the sheet 10 is expanded is explained.

In the adhesive liquid coating step, first, the nozzle 46 of the adhesive liquid coating apparatus 20 is positioned above the center of the wafer 2. Next, the on/off valve 50 of the adhesive liquid coating apparatus 20 is opened, and adhesive liquid having fluidity is supplied to the nozzle 46 from the adhesive liquid supply source 44. Then, as illustrated in FIG. 5, adhesive liquid 52 is dropped to the center of the face side 2a of the wafer 2 from the nozzle 46. After the adhesive liquid 52 is dropped to the wafer 2, the rotation plate 36 is rotated by the motor 42 via the belt 40, and the wafer 2 is rotated. As a result, the adhesive liquid 52 flows toward the outer periphery of the wafer 2 by centrifugal force and thus can coat the face side 2a of the wafer 2 at a substantially uniform thickness.

The adhesive liquid 52 having fluidity may, for example, be water-soluble resin including any of polyvinyl alcohol, polyethylene oxide, polyacrylamide, carboxymethylcellulose (CMC), resol-type phenolic resin, methylol urea resin, methylol melamine resin, vinyl acetate resin emulsion adhesive agent, and (PVA+borax). Alternatively, the adhesive liquid 52 may be silicon-based adhesive resin.

After the face side 2a of the wafer 2 is coated with the adhesive liquid 52, the sheet 10 is expanded, and external force is applied to the wafer 2, so that the wafer 2 is split up into individual device chips 6. Specifically, as illustrated in FIG. 6, by the frame support section 22 being lowered by the expanding mechanism 26, the upper surface of the frame support section 22 is lowered relative to the upper surface of the wafer support section 24. As a result, radial tension is applied to the sheet 10, and the sheet 10 is expanded. This leads to radial tension (external force) being applied to the wafer 2. As described above, since the modified layers 16 serving as the division initiating points are formed in the projected dicing lines 4 of the wafer 2, when radial tension (external force) is applied to the wafer 2, the wafer 2 is split up into individual device chips 6 along the projected dicing lines 4.

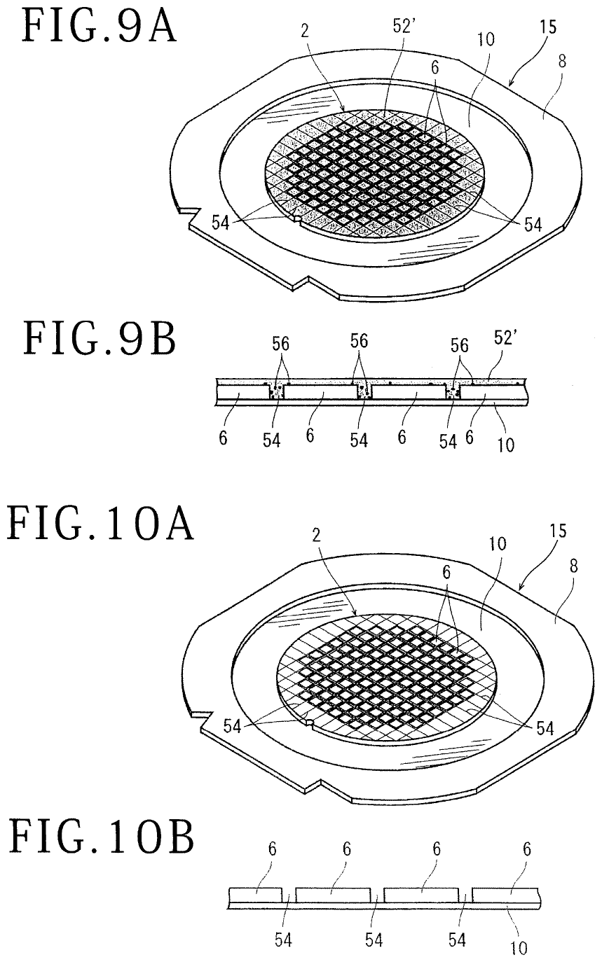

The adhesive liquid 52 enters splitting-up grooves 54 (see FIG. 9B) that are formed by the wafer 2 being split up into the device chips 6. In the present embodiment, the face side 2a of the wafer 2 is coated with the adhesive liquid 52 before the sheet 10 is expanded, so that, when the splitting-up grooves 54 are formed, the splitting-up grooves 54 are in a vacuumed state. Hence, the adhesive liquid 52 enters the splitting-up grooves 54 by atmospheric pressure together with capillary action. Accordingly, the adhesive liquid 52 preferably coats the face side 2a of the wafer 2 before the sheet 10 is expanded.

Further, when the wafer 2 is split up into individual device chips 6, processing swarf (dust) is generated due to breaking of the modified layers 16. An example of the processing swarf is denoted by reference sign 56 in FIG. 9B. In the present embodiment, since the face side 2a of the wafer 2 is coated with the adhesive liquid 52 before the sheet 10 is expanded, processing swarf 56 can be restrained from scattering and also be prevented from adhering to the face side (upper surface) of the device chip 6. Moreover, the processing swarf 56 remaining on the side surfaces of the device chips 6 can be captured by the adhesive liquid 52 that has entered the splitting-up grooves 54.

After the adhesive liquid coating step is carried out, the wafer 2 which has been divided into individual device chips 6 is held under suction on the upper surface of the suction chuck 34. That is, in a state in which the sheet 10 is expanded, the suction means of the wafer support section 24 is actuated. This generates suction force on the upper surface of the suction chuck 34, so that the wafer 2 which has been divided into individual device chips 6 is held under suction on the upper surface of the suction chuck 34. As a result, even if the frame support section 22 is raised to its original position, the spacing between the device chips 6 can be maintained.

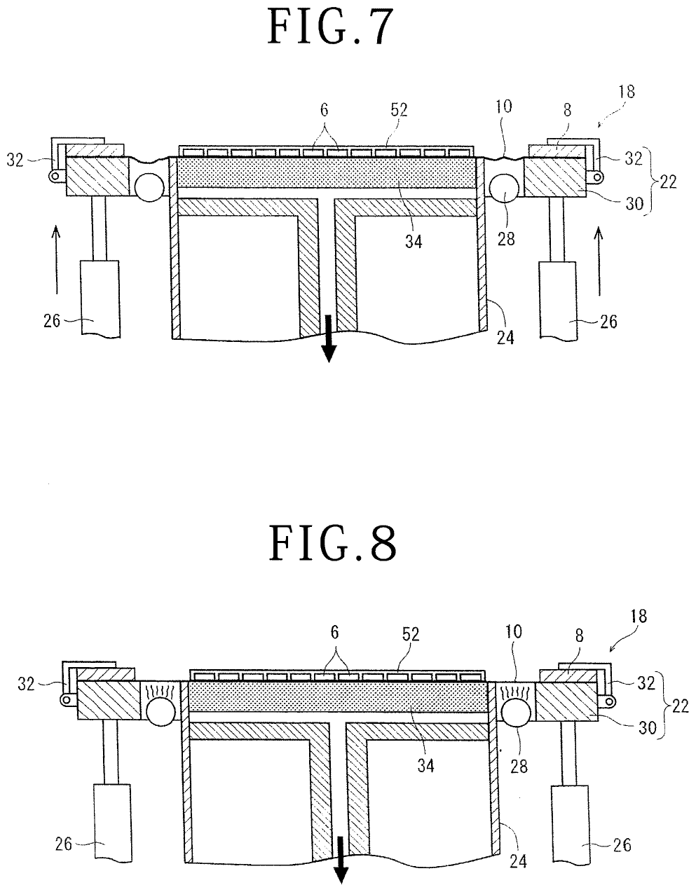

After the individual device chips 6 are held under suction on the suction chuck 34, the frame support section 22 is raised back to its original position (the position before the sheet 10 is expanded). As a result, while the spacing between the device chips 6 is maintained to be the spacing that is available when the sheet 10 is expanded, tension no longer acts on the sheet 10, so that slack occurs in the sheet 10 between the wafer 2 and the annular frame 8, as illustrated in FIG. 7.

Hence, after the frame support section 22 is raised back to its original position, the shrink unit 28 is actuated, so that the slack sheet 10 between the wafer 2 and the annular frame 8 is heated and shrunk. Specifically, hot air is sent or infrared rays are applied toward the upper side from an upper end of the shrink unit 28. This causes the sheet 10 to shrink and removes the slack in the sheet 10, as illustrated in FIG. 8. Consequently, even when holding the device chips 6 under suction on the suction chuck 34 is cancelled, the spacing between the device chips 6 is kept to the spacing available when the sheet 10 is expanded.

After the splitting-up step is carried out, a solidified film forming step of solidifying the adhesive liquid 52 in a state in which the sheet 10 is expanded and forming a solidified film 52′ is carried out (see FIGS. 9A and 9B). In the solidified film forming step, the wafer 2 coated with the adhesive liquid 52 is left untouched for a certain period of time, so that the adhesive liquid 52 is solidified by natural drying and the solidified film 52′ is formed. Alternatively, the adhesive liquid 52 may forcibly be solidified and the solidified film 52′ may be formed by application of infrared rays or the like and heating to the adhesive liquid 52. Forcibly solidifying the adhesive liquid 52 consumes less time than natural drying and is thus preferable in terms of productivity.

After the solidified film forming step is carried out, as illustrated in FIGS. 10A and 10B, a processing swarf removal step of peeling off the solidified film 52′ and removing the processing swarf 56 that has adhered to the side surfaces of the device chips 6 is carried out. As described above, upon entering the splitting-up grooves 54, the adhesive liquid 52 captures the processing swarf 56. Thus, peeling off the solidified film 52′ obtained by the adhesive liquid 52 being solidified from the device chips 6 makes it possible to remove the processing swarf 56 from the side surfaces of the device chips 6. Further, even if the processing swarf 56 is adhered to the face sides of the device chips 6, peeling off the solidified film 52′ makes it possible to remove the processing swarf 56 from the face sides of the device chips 6. Accordingly, the present invention can solve the problem caused by the processing swarf 56 adhered to the side surfaces and the face side of the device chips 6.

Further, after the processing swarf removal step is carried out, a cleaning step of cleaning the wafer 2 is performed. Though not illustrated, in the cleaning step, cleaning water is supplied to the wafer 2 (individual device chips 6) supported by the sheet 10, and the wafer 2 is cleaned. Further, drying air is jetted to the wafer 2 to remove the cleaning water and dry the wafer 2.

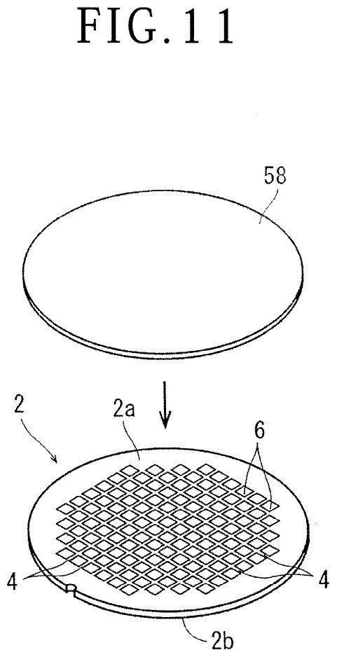

Next, the wafer processing method according to a second embodiment of the present invention will be described with reference to FIGS. 11 through 17B.

In the second embodiment, first, as illustrated in FIG. 11, a protective member disposing step of disposing a protective member 58 that protects the face side 2a of the wafer 2 is carried out. Yet, the protective member disposing step may be performed after the division initiating point forming step. As the protective member 58, a circular adhesive tape or thermocompression sheet which has a diameter substantially equal to that of the wafer 2 can be used.

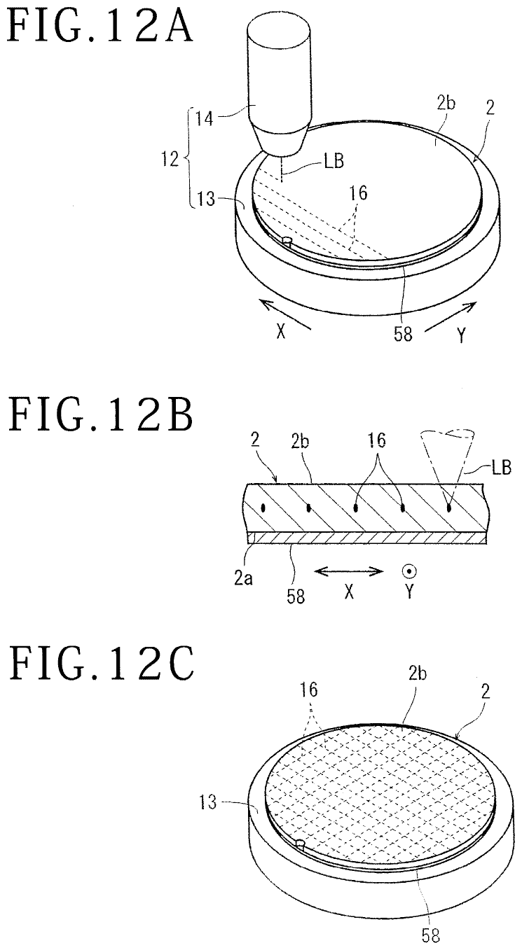

In the present embodiment, after the protective member disposing step is carried out, the division initiating point forming step of forming division initiating points in the projected dicing lines 4 is carried out. The division initiating point forming step can, for example, be carried out by use of the abovementioned laser processing apparatus 12. Note that, in FIGS. 2A and 2B, the chuck table of the laser processing apparatus 12 is not illustrated for the convenience of description, but in FIGS. 12A and 12C, the chuck table of the laser processing apparatus 12 is denoted by the reference sign 13.

As illustrated in FIG. 12A, in the division initiating point forming step, first, the reverse side 2b of the wafer 2 is faced upward, and the wafer 2 is held under suction on the upper surface of the chuck table 13. Next, infrared rays are applied from the imaging unit, and the face side 2a of the wafer 2 is imaged by the infrared rays that have transmitted through the reverse side 2b of the wafer 2. Subsequently, the projected dicing lines 4 in the first direction are aligned in the X-axis direction in reference to the image of the wafer 2 captured by the imaging unit. Further, the laser beam LB is focused on the projected dicing lines 4 that have been aligned in the X-axis direction, and the focused spot of the laser beam LB is positioned inside the projected dicing lines 4.

Next, while the chuck table 13 is processing fed in the X-axis direction, the laser beam LB having a wavelength transmittable through the wafer 2 is applied to the wafer 2 from the light condenser 14. As a result, modified layers 16 that serve as the division initiating points are formed inside the wafer 2 along the projected dicing lines 4 (see FIG. 12B). Note that, from the viewpoint of preventing reduced deflective strength of the device chips 6, the modified layers 16 are preferably formed at portions to be removed by grinding in the reverse side 2b of the wafer 2 in a reverse side grinding step to be described later.

Subsequently, the chuck table 13 is indexing fed in the Y-axis direction relative to the light condenser 14 by an amount of spacing between the projected dicing lines 4 in the Y-axis direction. Further, with the application of the laser beam LB and the indexing feed of the chuck table 13 being alternately repeated, the modified layers 16 are formed inside the wafer 2 along all of the projected dicing lines 4 in the first direction that have been aligned in the X-axis direction.

Then, after the chuck table 13 is rotated by 90 degrees, the application of the laser beam LB and the indexing feed of the chuck table 13 are alternately repeated. As a result, the modified layers 16 are formed inside the wafer 2 along all of the projected dicing lines 4 in the second direction that are perpendicular to the projected dicing lines 4 in the first direction in which the modified layers 16 have already been formed. In this way, the division initiating point forming step is carried out, and as illustrated in FIG. 12C, the modified layers 16 are formed in a grid pattern inside the wafer 2 along the projected dicing lines 4 in a grid pattern.

The division initiating point forming step as described above can, for example, be carried out under the following processing conditions.
Wavelength of pulsed laser beam: 1,342 nm
Average output: 1.0 W
Repetition frequency: 90 kHz
Feeding speed: 700 mm/s

Here, an example in which the modified layers 16 are formed by application of the laser beam LB from the reverse side 2b of the wafer 2 has been explained. Yet, in the division initiating point forming step, the modified layers 16 may be formed by application of the laser beam LB from the face side 2a of the wafer 2 via the protective member 58. Alternatively, the protective member disposing step may be performed after the division initiating point forming step.

Further, in the example explained above, the division initiating point is the modified layer 16, but may instead be a groove having a depth corresponding to the finishing thickness of the device chip 6. The groove as the division initiating point is formed on the face side 2a of the wafer 2 along the projected dicing lines 4. Further, the groove as the division initiating point may be formed by ablation processing using application of laser beams or cutting processing using a dicing apparatus.

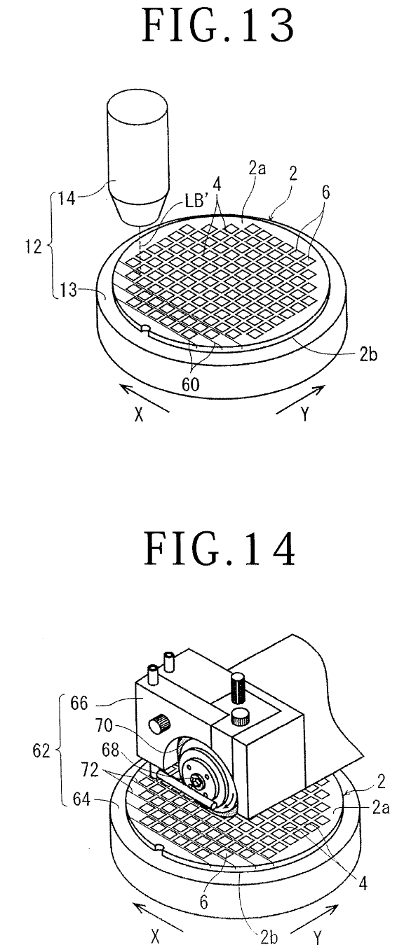

First, with reference to FIG. 13, a case where grooves as division initiating points are formed by ablation processing is explained. In this case, before the protective member 58 is disposed on the face side 2a of the wafer 2, the wafer 2 is held under suction on the chuck table 13 with the face side 2a facing upward. Next, the projected dicing lines 4 in the first direction are aligned in the X-axis direction, and a laser beam LB′ having a wavelength absorbable by the wafer 2 is focused on the projected dicing lines 4. Further, the focused spot of the laser beam LB′ is positioned on the face side 2a. Note that the face side 2a is preferably covered with a protective film so as to prevent debris from adhering to the face side 2a of the wafer 2.

Then, while the chuck table 13 is being processing fed in the X-axis direction, the laser beam LB′ having a wavelength absorbable by the wafer 2 is applied to the wafer 2. As a result, a laser processing groove 60 having a depth corresponding to the finishing thickness of the device chip 6 is formed on the face side 2a along the projected dicing lines 4. Moreover, as in the case in which the modified layers 16 are formed, application of the laser beam LB′ and indexing feed of the chuck table 13 are alternately repeated, so that the laser processing grooves 60 are formed in a grid pattern on the face side 2a of the wafer 2 along the projected dicing lines 4 in a grid pattern.

In a case where the laser processing grooves 60 are formed as division initiating points, for example, the division initiating point forming step can be performed under the following conditions.
Wavelength of laser beam: 355 nm
Average output: 2.0 W
Repetition frequency: 80 kHz
Feeding speed: 300 mm/s

Next, with reference to FIG. 14, a case in which grooves as division initiating points are formed by cutting processing is explained. In the case where the grooves are formed by cutting processing, for example, a dicing apparatus 62 illustrated in FIG. 14 can be used. The dicing apparatus 62 includes a chuck table 64 that holds under suction the wafer 2 and a cutting unit 66 that cuts the wafer 2 held under suction on the chuck table 64. The cutting unit 66 includes a spindle 68 configured to be rotatable about an axis in the Y-axis direction and an annular cutting blade 70 fixed to a distal end of the spindle 68.

Also in a case where the grooves as the division initiating points are formed by cutting processing, as in the case of using ablation processing, the wafer 2 is held under suction on an upper surface of the chuck table 64 with the face side 2a facing upward, before the protective member 58 is disposed on the face side 2a of the wafer 2. Next, a cutting edge of the cutting blade 70 rotated at high speed is caused to cut into the projected dicing lines 4 in the first direction that are aligned in the X-axis direction to a depth corresponding to the finishing thickness of the device chips 6 from the face side 2a, and the chuck table 64 is processing fed in the X-axis direction while cutting water is supplied to a portion where the cutting edge of the cutting blade 70 is caused to cut in. As a result, cutting grooves 72 each having a depth corresponding to the finishing thickness of the device chips 6 are formed along the projected dicing lines 4. Also in a case where the cutting processing is to be performed, formation of the cutting grooves 72 and indexing feed of the chuck table 64 are alternately repeated, and the cutting grooves 72 are formed on the face side 2a of the wafer 2 in a grid pattern along the projected dicing lines 4 in a grid pattern.

In a case where the cutting grooves 72 are to be formed as division initiating points, for example, the division initiating point forming step can be carried out under the following conditions.
Diameter of cutting blade: 50 mm
Rotational speed of cutting blade: 30,000 rpm
Supply amount of cutting water: 2 L/min
Feeding speed: 50 mm/s

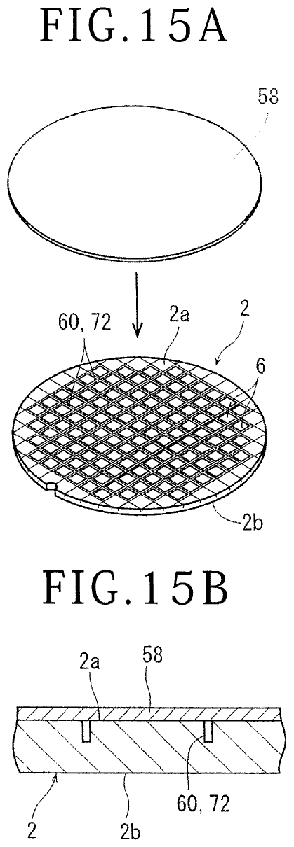

Since the grooves 60 and 72 as the division initiating points are formed on the face side 2a of the wafer 2, in a case where the grooves 60 and 72 are to be formed as the division initiating points, the protective member disposing step is performed after the division initiating point forming step is carried out, as illustrated in FIGS. 15A and 15B.

After the protective member disposing step and the division initiating point forming step are carried out, a reverse side grinding step of holding the protective member 58 side on the chuck table and grinding the wafer 2 on the reverse side 2b to finish it to a desired thickness, while forming the dividing grooves in the projected dicing lines 4 and dividing the wafer 2 into individual device chips 6 is performed.

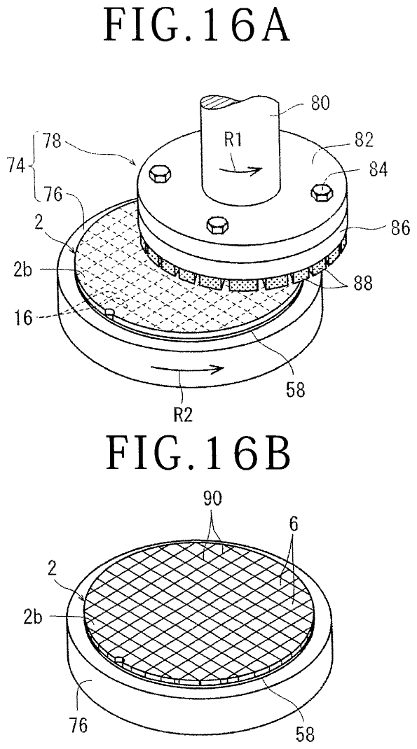

The reverse side grinding step can, for example, be performed with use of a grinding apparatus 74 illustrated in FIG. 16A. The grinding apparatus 74 includes a chuck table 76 that holds under suction the wafer 2 and a grinding unit 78 that grinds the wafer 2 held under suction on the chuck table 76. The grinding unit 78 includes a spindle 80 extending in a vertical direction and a circular plate-shaped wheel mount 82 that is fixed to a lower end of the spindle 80. An annular grinding wheel 86 is fastened to a lower surface of the wheel mount 82 by bolts 84. Moreover, a plurality of grindstones 88 disposed in an annular shape at intervals along the circumferential direction are fixed to an outer peripheral portion on a lower surface of the grinding wheel 86.

In the reverse side grinding step, first, the reverse side 2b of the wafer 2 is faced upward, and the wafer 2 is held under suction on an upper surface of the chuck table 76. Next, the spindle 80 is rotated at a predetermined rotational speed (for example, 6,000 rpm) in a direction indicated by an arrow R1 in FIG. 16A. Further, the chuck table 76 is rotated at a predetermined rotational speed (for example, 300 rpm) in a direction indicated by an arrow R2. Subsequently, the spindle 80 is lowered to bring the grindstones 88 into contact with the reverse side 2b of the wafer 2, while cutting water is supplied to the portion where the grindstones 88 come into contact with the reverse side 2b. Thereafter, the spindle 80 is lowered at a predetermined grinding feed speed (for example, 1.0 μm/s). As a result, the reverse side 2b of the wafer 2 is ground, and the wafer 2 is thinned to a finishing thickness of the device chips 6.

In the case where the modified layers 16 are formed as the division initiating points, cracks extend in the thickness direction of the wafer 2 from the modified layers 16 by the pressing force that acts when the wafer 2 is ground, and the wafer 2 is divided into the individual device chips 6 as illustrated in FIG. 16B. Moreover, since dividing grooves 90 (grooves that reach the reverse side 2b from the face side 2a) are formed by the cracks extending from the modified layers 16, the side surfaces of the device chips 6 become cleavage surfaces.

In contrast, in the case where the laser processing grooves 60 or the cutting grooves 72 are formed as the division initiating points, the depths of the grooves 60 and 72 each correspond to the finishing thickness of the device chips 6, so that grinding the reverse side 2b of the wafer 2 to the thickness described above causes the grooves 60 and 72 to appear on the reverse side 2b of the wafer 2 and configure the dividing grooves 90. As a result, the wafer 2 is divided into individual device chips 6. After the reverse side 2b of the wafer 2 is ground, cleaning water is supplied to the reverse side 2b of the wafer 2 to clean the wafer 2, and dry air is jet to the reverse side 2b of the wafer 2 to dry the wafer 2.

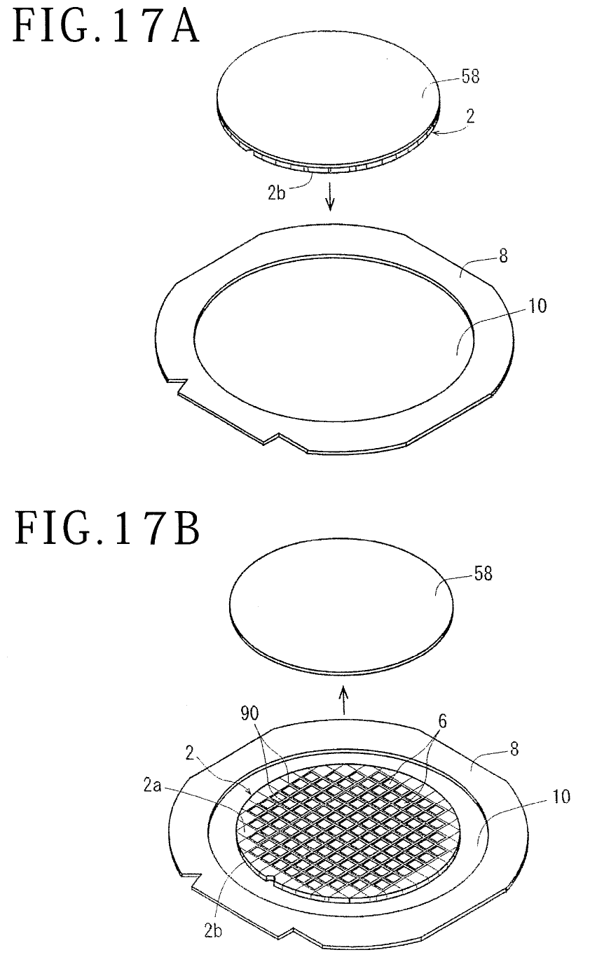

After the reverse side grinding step is carried out and the wafer 2 is cleaned, a sheet disposing step of disposing the sheet 10 having elasticity on the reverse side 2b of the wafer 2 and removing the protective member 58 from the face side 2a of the wafer 2 is performed. As illustrated in FIG. 17A, in the sheet disposing step, first, a circular sheet 10 whose peripheral edge is fixed to the annular frame 8 is disposed on the reverse side 2b of the wafer 2. The sheet 10 may be an elastic adhesive tape or thermocompression sheet. After the sheet 10 is disposed on the reverse side 2b of the wafer 2, as illustrated in FIG. 17B, the protective member 58 is removed from the face side 2a of the wafer 2.

After the sheet disposing step is carried out, an expanding step of expanding the sheet 10 to expand the spacing between the individual device chips 6 is performed. The expanding step includes an adhesive liquid coating step of coating the exposed surface (face side 2a) of the wafer 2 with the adhesive liquid 52 having fluidity before or after the sheet 10 is expanded and causing the adhesive liquid 52 to enter the dividing grooves 90. The expanding step and the adhesive liquid coating step can be performed with use of the expanding apparatus 18 and the adhesive liquid coating apparatus 20, as in the case of the splitting-up step and the adhesive liquid coating step according to the first embodiment.

In the expanding step, first, the annular frame 8 is placed on the annular member 30 of the frame support section 22 and is fixed to the annular member 30 by the clamps 32 (see FIG. 5). Next, the wafer 2 is placed on the suction chuck 34 of the wafer support section 24 via the sheet 10 with the face side 2a facing upward. At this time, the height of the upper surface of the frame support section 22 and the height of the upper surface of the wafer support section 24 are made substantially the same. Further, at this point in time, the suction means of the wafer support section 24 is not actuated, and the wafer 2 is not held under suction on the suction chuck 34.

Subsequently, in the expanding step, after the annular frame 8 is supported by the frame support section 22 and the wafer 2 is supported by the wafer support section 24, the adhesive liquid coating step is performed. In the adhesive liquid coating step, after the adhesive liquid 52 is dropped from the nozzle 46 to the center of the wafer 2, the wafer 2 is rotated. As a result, the adhesive liquid 52 flows toward the outer periphery of the wafer 2 by centrifugal force, so that the face side 2a of the wafer 2 can be coated with the adhesive liquid 52 at a uniform thickness. Note that the examples of the adhesive liquid provided above (for example, polyvinyl alcohol) may be used as the adhesive liquid 52.

After the face side 2a of the wafer 2 is coated with the adhesive liquid 52, the sheet 10 is expanded to expand the spacing between the individual device chips 6. Specifically, by the frame support section 22 being lowered by the expanding mechanism 26, the upper surface of the frame support section 22 is lowered relative to the upper surface of the wafer support section 24. As a result, radial tension is applied to the sheet 10, so that the sheet 10 is expanded, and the spacing between the device chips 6 is expanded (see FIG. 6).

When the spacing between the device chips 6 is expanded and the width of each of the dividing grooves 90 between the device chips 6 is increased, the adhesive liquid 52 enters the dividing grooves 90. In the second embodiment, since the dividing grooves 90 are already formed before the spacing between the device chips 6 is expanded, at the time when the face side 2a of the wafer 2 is coated with the adhesive liquid 52 (before the expansion), the adhesive liquid 52 may enter the dividing grooves 90. Yet, expanding the spacing between the device chips 6 allows more amount of adhesive liquid 52 to enter the dividing grooves 90 than that before the expansion. Further, the adhesive liquid 52 that has entered the dividing grooves 90 captures the processing swarf 56 that remains on the side surfaces of the device chips 6. Note that the processing swarf 56 in the second embodiment includes, in addition to dust caused by breaking of the modified layers 16, cutting swarf that is generated at the time of formation of the cutting grooves 72, grinding swarf generated in the reverse side grinding step and squeezed into the dividing grooves 90 by the grindstones 88, and the like.

After the adhesive liquid coating step is performed, the wafer 2 that has been divided into individual device chips 6 is held under suction on the upper surface of the suction chuck 34. That is, in a state in which the sheet 10 is expanded, the suction means of the wafer support section 24 is actuated. As a result, suction force is generated on the upper surface of the suction chuck 34, so that the wafer 2 that has been divided into individual device chips 6 is held under suction on the upper surface of the suction chuck 34. Consequently, even when the frame support section 22 is raised back to its original position, the spacing between the device chips 6 can be maintained.

After the individual device chips 6 are held under suction on the suction chuck 34, the frame support section 22 is raised back to its original position (position before the sheet 10 is expanded). As a result, while the spacing between the device chips 6 is kept to the spacing available when the sheet 10 is expanded, tension no longer acts on the sheet 10, so that slack occurs in the sheet 10 between the wafer 2 and the annular frame 8 (see FIG. 7).

As such, also in the second embodiment, after the frame support section 22 is raised back to its original position, the shrink unit 28 is actuated to heat and shrink the slack sheet 10 between the wafer 2 and the annular frame 8. Specifically, hot air is sent or infrared rays are applied toward the upper side from the upper end of the shrink unit 28. This causes the sheet 10 to shrink and allows the slack in the sheet 10 to be removed (see FIG. 8). Consequently, even when holding the device chips 6 under suction on the suction chuck 34 is cancelled, the spacing between the device chips 6 is kept to the spacing available when the sheet 10 is expanded.

After the expanding step is carried out, as in the first embodiment, the solidified film forming step of solidifying the adhesive liquid 52 in a state in which the sheet 10 is expanded and forming the solidified film 52′ is performed (see FIGS. 9A and 9B).

After the solidified film forming step is carried out, as in the first embodiment, the processing swarf removal step of peeling off the solidified film 52′ and removing the processing swarf 56 adhered to the side surfaces of the device chips 6 is performed (see FIGS. 10A and 10B). Upon entering the dividing grooves 90, the adhesive liquid 52 captures the processing swarf 56. Hence, peeling off the solidified film 52′ obtained by the adhesive liquid 52 being solidified from the device chips 6 makes it possible to remove the processing swarf 56 from the side surfaces of the device chips 6. Moreover, even if processing swarf 56 is adhered to the face sides of the device chips 6, peeling off the solidified film 52′ makes it possible to remove the processing swarf 56 from the face sides of the device chips 6. Accordingly, also in the second embodiment, the problem caused by the processing swarf 56 adhered to the side surfaces and the face sides of the device chips 6 can be solved.

Further, also in the second embodiment, after the processing swarf removal step is carried out, the cleaning step of cleaning the wafer 2 is preferably performed.

As described above, in both the first and second embodiments, the adhesive liquid 52 having fluidity captures the processing swarf 56 that has adhered to the side surfaces of the device chips 6. Hence, peeling off the solidified film 52′ obtained by the adhesive liquid 52 being solidified makes it possible to remove the processing swarf 56 from the side surfaces of the device chips 6. As a result, no processing swarf 56 would fall off or scatter from the side surfaces of the device chips 6 in the subsequent steps including wire bonding, die bonding, lamination of the device chips 6, and the like. Further, even if the processing swarf 56 is adhered to the face sides of the device chips 6, the processing swarf 56 can be removed from the face sides of the device chips 6 by peeling off the solidified film 52′. Accordingly, in both the first and second embodiments, a problem caused by the processing swarf 56 adhered to the side surfaces and the face sides of the device chips 6 can be solved.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer processing method that divides a wafer which has a face side on which a plurality of device chips are formed by being partitioned by a plurality of projected dicing lines into individual device chips, the method comprising:
a division initiating point forming step of forming division initiating points in the projected dicing lines;
a sheet disposing step of disposing, on the wafer, a sheet having elasticity before or after the division initiating point forming step;
an adhesive liquid coating step of coating an exposed surface of the wafer with adhesive liquid having fluidity;
a splitting-up step of splitting up the wafer into individual device chips by expanding the sheet and applying external force to the wafer;
a solidified film forming step of forming a solidified film by solidifying the adhesive liquid in a state in which the sheet is expanded, after the splitting-up step; and
a processing swarf removal step of removing processing swarf adhered to side surfaces of the device chips by peeling off the solidified film, wherein,
in the splitting-up step, the adhesive liquid that has coated the exposed surface of the wafer in the adhesive liquid coating step is caused to enter dividing grooves formed by splitting-up of the wafer.

2. The wafer processing method according to claim 1, wherein,
in the division initiating point forming step, modified layers that serve as the division initiating points are formed by application of a laser beam having a wavelength transmittable through the wafer to the wafer with a focused spot of the laser beam being positioned inside the wafer corresponding to the projected dicing lines.

3. The wafer processing method according to claim 1, further comprising:
a cleaning step of cleaning the wafer after the processing swarf removal step.

4. The wafer processing method according to claim 1, wherein
the adhesive liquid is water-soluble resin including any of polyvinyl alcohol, polyethylene oxide, polyacrylamide, carboxymethylcellulose, resol-type phenolic resin, methylol urea resin, methylol melamine resin, vinyl acetate resin emulsion adhesive agent, and (polyvinyl alcohol+borax) or silicon-based adhesive resin.

5. A wafer processing method that divides a wafer which has a face side on which a plurality of devices are formed by being partitioned by a plurality of projected dicing lines into individual device chips, the method comprising:
a division initiating point forming step of forming division initiating points in the projected dicing lines;
a protective member disposing step of disposing a protective member that protects the face side of the wafer, before or after the division initiating point forming step;
a reverse side grinding step of finishing the wafer to a desired thickness by holding the protective member side on a chuck table and grinding a reverse side of the wafer after the division initiating point forming step, while dividing the wafer into individual device chips by forming dividing grooves in the projected dicing lines;
a sheet disposing step of disposing a sheet having elasticity on the reverse side of the wafer and removing the protective member from the face side of the wafer;
an adhesive liquid coating step of coating an exposed surface of the wafer with adhesive liquid having fluidity;
an expanding step of expanding the sheet to expand a spacing between the individual device chips;
a solidified film forming step of forming a solidified film by solidifying the adhesive liquid in a state in which the sheet is expanded, after the expanding step; and
a processing swarf removal step of removing processing swarf adhered to side surfaces of the device chips by peeling off the solidified film, wherein,
in the expanding step, the adhesive liquid that has coated the wafer in the adhesive liquid coating step is caused to enter the dividing grooves.

6. The wafer processing method according to claim 5, wherein,
in the division initiating point forming step, modified layers that serve as division initiating points are formed by application of a laser beam having a wavelength transmittable through the wafer to the wafer with a focused spot of the laser beam being positioned inside the wafer corresponding to the projected dicing lines.

7. The wafer processing method according to claim 5, further comprising:
a cleaning step of cleaning the wafer after the processing swarf removal step.

8. The wafer processing method according to claim 5, wherein
the adhesive liquid is water-soluble resin including any of polyvinyl alcohol, polyethylene oxide, polyacrylamide, carboxymethylcellulose, resol-type phenolic resin, methylol urea resin, methylol melamine resin, vinyl acetate resin emulsion adhesive agent, and (polyvinyl alcohol+borax) or silicon-based adhesive resin.
